(19) United States
(12) Patent Application Publication
(10) Pub. No.: US 2014/0118009 A1
(43) Pub. Date: May 1, 2014

(54) CAPACITIVE SENSING COMPONENT, PREPARATION METHOD THEREOF AND TOUCH SCREEN HAVING THE SAME

(71) Applicant: SHENZHEN O-FILM TECH CO., LTD., Shenzhen, Guangdong (CN)

(72) Inventors: Zhizheng Cheng, Shenzhen (CN); Kai Meng, Shenzhen (CN); Rongjun Cai, Nanchang (CN)

(73) Assignee: SHENZHEN O-FILM TECH CO., LTD., Shenzhen, Guangdong (CN)

(21) Appl. No.: 14/000,163

(22) PCT Filed: Dec. 20, 2012
(86) PCT No.: PCT/CN2012/087082

§ 371 Date: Aug. 16, 2013

(30) Foreign Application Priority Data
Apr. 19, 2012 (CN) 201210116195.7

(51) Int. Cl. G01R 27/26

(52) U.S. Cl. CPC G01R 27/2605
USPC 324/658; 430/319

(57) ABSTRACT

A capacitive sensing component includes a substrate and a patterned sensing layer formed on the substrate; the patterned sensing layer includes a plurality of sensing electrodes, the plurality of sensing electrodes are formed of a metal mesh laying on the substrate. The cost of the capacitive sensing component is low. A preparation method of a capacitive sensing component and a touch screen are also provided.

### FIELD OF THE INVENTION

The present invention relates to a capacitive sensing component, a preparation method thereof and a touch screen having the capacitive sensing component.

### BACKGROUND OF THE INVENTION

In recently, the capacitive touch screen is more and more favored by the market because it has a lot of advantages, such as high transparency, multi-touch, long life and so on. Currently, the transparent conductive material (indium tin oxide, ITO) is coated on a PET or a glass substrate to form a capacitive sensing component by vacuum evaporation deposition or magnetron sputtering. The capacitive sensing component, the cover plate, and the circuit board are assembled to form a touch screen.

However, indium is a rare earth element, which has relatively small reserves in nature, and is expensive, thereby bringing high costs to the capacitive sensing component and the touch screen with the capacitive sensing component.

### SUMMARY OF THE INVENTION

One object of the present invention is to provide a low-cost capacitive sensing component, a preparation method thereof and a touch screen having the capacitive sensing component.

A capacitive sensing component includes:

a substrate and a patterned sensing layer formed on the substrate, the patterned sensing layer includes a plurality of sensing electrodes, the plurality of sensing electrodes are formed by a metal mesh arranged on the substrate.

In one embodiment, the width of the line of the metal mesh is greater than or equals to 45 nm and less than or equals to 40000 nm.

In one embodiment, the metal mesh is made of a material selected from the group consisting of copper, molybdenum-aluminum-molybdenum alloy, and copper-nickel alloy.

In one embodiment, a surface of the metal mesh is provided with an anti-oxidation layer, the anti-oxidation layer is made of a material selected from the group consisting of gold, platinum, and nickel.

A preparation method of a capacitive sensing component includes the following steps:

forming a metal layer on a substrate; and

processing the metal layer to form a metal mesh by exposure and development, and a plurality of sensing electrodes arrayed on the substrate are formed by the metal mesh, and a patterned sensing layer is formed on the substrate.

In one embodiment, the metal layer is made of a material selected from the group consisting of copper, molybdenum-aluminum-molybdenum alloy, and copper-nickel alloy.

A touch screen includes:

the capacitive sensing component according to any one as mentioned;

a cover plate laminated on the patterned sensing layer of the capacitive sensing component.

In one embodiment, the sensing electrodes include a first sensing electrode and a second sensing electrode, the first sensing electrode and the second sensing electrode are alternately arranged.

In one embodiment, the number of the capacitive sensing components is two, the substrate of one of the capacitive sensing components is laminated on the patterned sensing layer of the other capacitive sensing component, a plurality of sensing electrodes of the patterned sensing layer of one of the capacitive sensing components are arrayed along a first direction, a plurality of sensing electrodes of the second patterned sensing layer of the other capacitive sensing component are arrayed along a second direction.

In one embodiment, the first direction is perpendicular to the second direction.

In the capacitive sensing component, a preparation method thereof and a touch screen having the capacitive sensing component, the sensing electrodes of the patterned sensing layer are made by metal mesh, avoiding the use of indium tin oxide, thus the cost of the capacitive sensing component is low.

### BRIEF DESCRIPTION OF THE DRAWINGS

FIG. 1 is a schematic, cross-sectional view of an embodiment of a touch screen;

FIG. 2 is a schematic, plane view of a metal mesh of the touch screen shown in FIG. 1;

FIG. 3 is a schematic, plane view of another embodiment of a metal mesh of the touch screen;

FIG. 4 is a schematic, plane view of another embodiment of a metal mesh of the touch screen;

FIG. 5 is a schematic, plane view of another embodiment of a metal mesh of the touch screen;

FIG. 6 is an assembly schematic, plane view of the first capacitive sensing component and the second capacitive sensing component of the touch screen shown in FIG. 1;

FIG. 7 is an assembly schematic, plane view of another embodiment of the first capacitive sensing component and the second capacitive sensing component of the touch screen; and

FIG. 8 is a schematic, plane view of another embodiment of the patterned sensing layer of the first capacitive sensing component.

### DETAILED DESCRIPTION OF THE EMBODIMENTS

Illustrative embodiments of the invention are described below. The following explanation provides specific details for a thorough understanding of and enabling description for these embodiments. One skilled in the art will understand that the invention may be practiced without such details. In other instances, well-known structures and functions have not been shown or described in detail to avoid unnecessarily obscuring the description of the embodiments.

Unless the context clearly requires otherwise, throughout the description and the claims, the words “comprise,” “comprising,” and the like are to be construed in an inclusive sense as opposed to an exclusive or exhaustive sense; that is to say, in the sense of “including, but not limited to.” Words using the singular or plural number also include the plural or singular number respectively. Additionally, the words “herein,”“above,” “below” and words of similar import, when used in this application, shall refer to this application as a whole and not to any particular portions of this application. When the claims use the word “or” in reference to a list of two or more items, that word covers all of the following interpretations of the word: any of the items in the list, all of the items in the list and any combination of the items in the list.

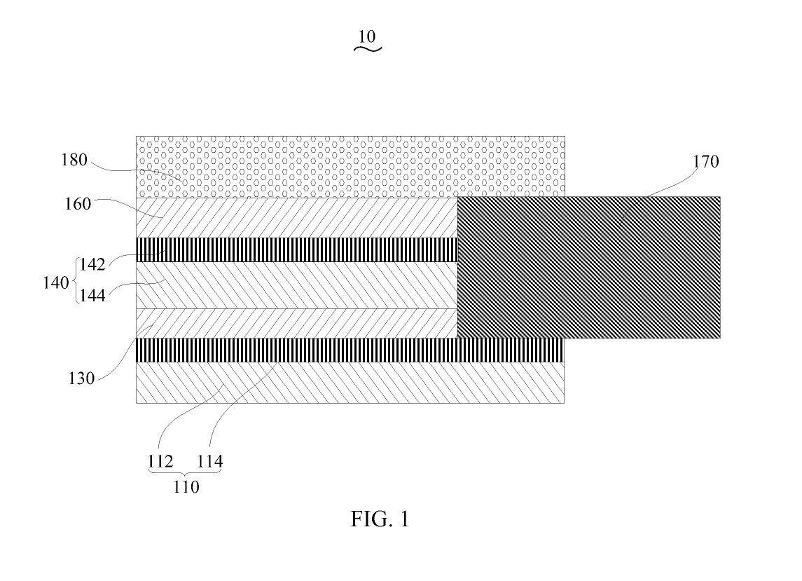

Referring to FIG. 1, an embodiment of a touch screen 10 includes a first capacitive sensing component 110, a first adhesive layer 130, a second capacitive sensing component 140, a second adhesive layer 160, a cover plate 170 and a circuit board 180. The first capacitive sensing component 110 is consisted of a first substrate 112 and a first patterned sensing layer 114, the second capacitive sensing component 140 is consisted of a second substrate 142 and a second patterned sensing layer 144.

The first substrate 112 is an optical film or a glass plate. In the illustrated embodiment, the first substrate 112 is made of a material of polyethylene terephthalate (PET).

The first patterned sensing layer 114 is formed on the surface of the first substrate 112.

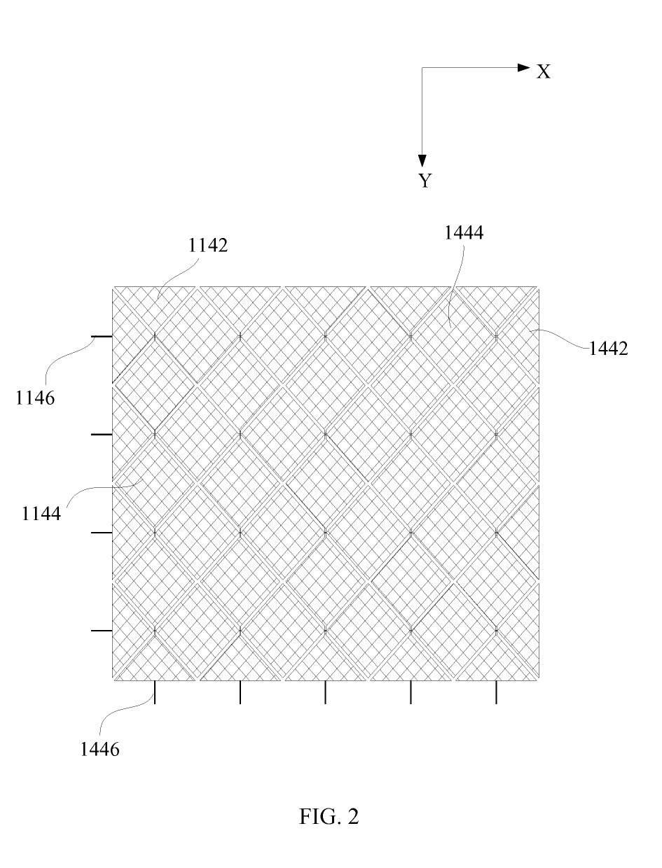

Referring to FIG. 2, the first patterned sensing layer 114 includes a plurality of first sensing electrodes 1142 arrayed along a first direction X. The first sensing electrodes 1142 are made by a metal mesh 20 arranged on the surface of the first substrate 112.

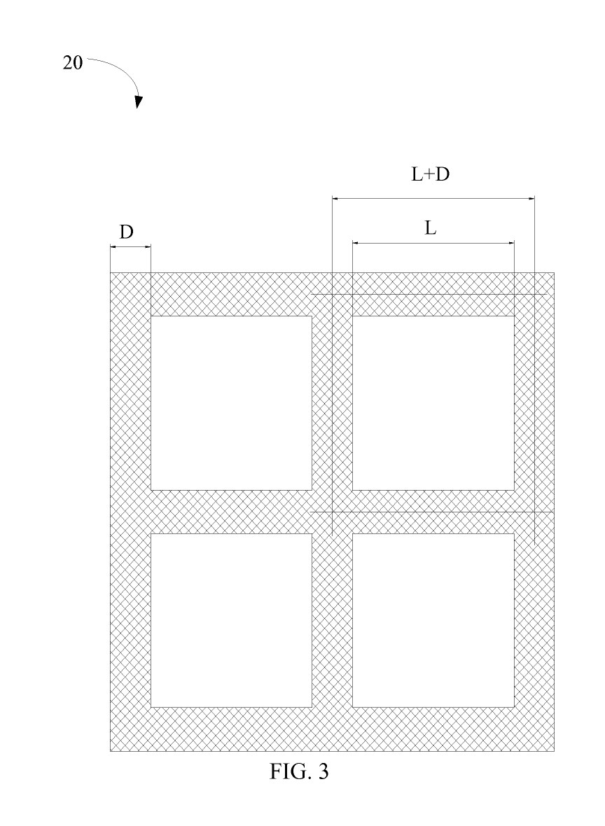

Referring to FIG. 3, in the illustrated embodiment, the metal mesh 20 is made of copper, molybdenum-aluminum-molybdenum alloy or copper-nickel alloy. In order to avoid the oxidation of the metal mesh 20, an anti-oxidation layer is formed on the surface of the metal mesh 20, the anti-oxidation layer is made of a material of inert metal, such as gold, platinum or nickel and so on.

The width (D) of the line of the metal mesh 20 is greater than or equals to 45 nm and less than or equals to 40000 nm. It should be noted that the width (D) of the line of the metal mesh 20 has an impact to the resolution of the touch screen 10, when width (D) of the line of the metal mesh 20 is too large, the line will be seen, thus the resolution of the touch screen 10 may be impacted. Preferably, the width (D) of the line of the metal mesh 20 is greater than or equals to 45 nm and less than or equals to 5000 nm.

In order to ensure the sensitivity of the touch screen 10 to the signal, the relationship of the aperture ratio (K) of the metal mesh 20 and the transmittance (T₁) of the first capacitive sensing component 110 and the transmittance (T₂) of the first substrate 112 is as following: T₁=T₂*K. Thus the aperture ratio of the metal mesh 20 satisfied with desired conditions may be calculated according to the designed transmittance of the first capacitive sensing component 110.

Taking the following metal mesh 20 as an example, the shape of the grid of the metal mesh 20 is square. The width of the line of the metal mesh 20 is D, the aperture width of the grid of the metal mesh 20 is L. The metal mesh 20 may be viewed as consisting of a plurality of unit cells with the length of side is D+L, the aperture ratio (K) of the metal mesh 20=the area of the unit cells is divided by that of the metal mesh 20. Specifically, in the illustrated embodiment, K=L²/(L+D)².

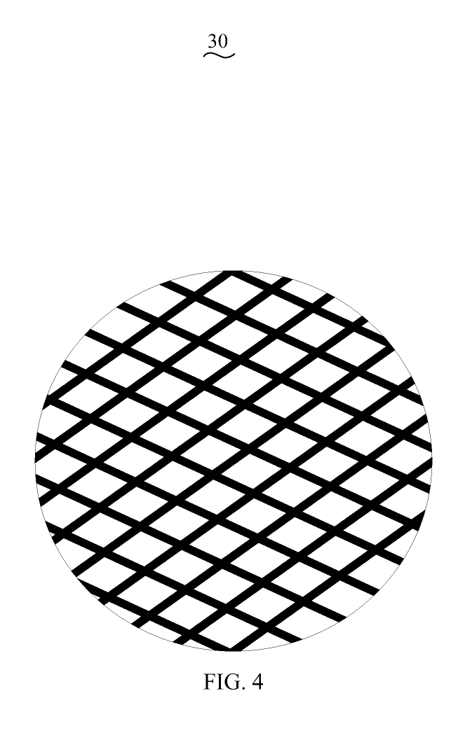

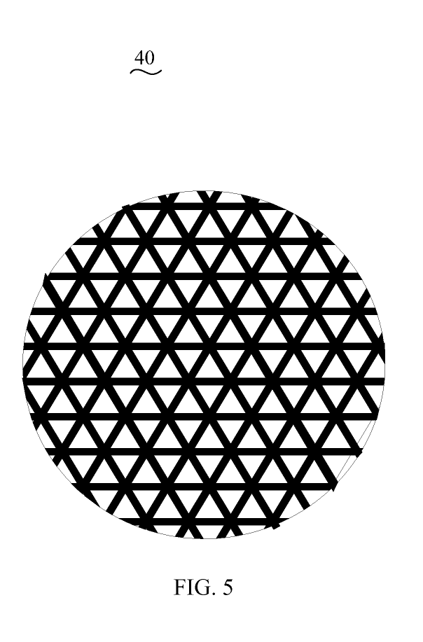

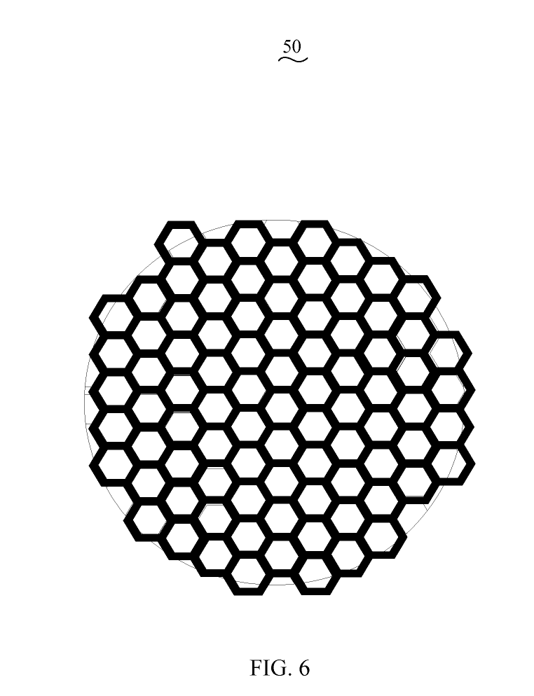

It should be noted that the grid of the metal mesh 20 is not limited to square as shown in FIG. 2, and may be polygonal, for example, the grids of the metal mesh 30, the metal mesh 40 and the metal mesh 50 respectively shown in FIG. 4 to FIG. 6 are prismatic, triangular or hexagonal.

Referring to FIG. 2, in the illustrated embodiment, each of the first sensing electrodes 1142 includes a plurality of sensing units 1144 connected in turn and a wire 1146. The sensing units 1144 are substantially prismatic, a plurality of the sensing units 1144 are connected in turn along a second direction Y, the two opposite corners of one of the sensing units 1144 are connected to a corner of the two adjacent sensing units 1144, respectively. It should be noted that, since the first substrate 114 is substantially rectangular, the two sensing units 1144 on the two ends are triangular or polygonal for cutting.

The wire 1146 is electrically connected to the sensing units 1144 located on one end of the first sensing electrode 1142. In the illustrated embodiment, the wires 1146 are metal wire, and the wires 1146 and the first sensing electrode 1142 connected to the wire 1146 are integrated.

Referring to FIG. 1, the second substrate 142 is bonded to the first pattern sense layer 114 via the first adhesive layer 130. The first adhesive layer 130 is optical adhesive, specifically, the material of the first adhesive layer 130 is silicone or acrylic adhesive. The acrylic adhesive includes acrylic adhesive and methyl acrylic adhesive.

The second substrate 142 is an optical film or a glass plate. In the illustrated embodiment, the material of the first substrate 112 is PET. The size of the second substrate 142 is smaller than the size of the first substrate 112.

Referring to FIG. 2, the second patterned sensing layer 144 is formed on the surface of the second substrate 142. The second patterned sensing layer 144 includes a plurality of second sensing electrodes 1442 arrayed in a second direction Y. The second sensing electrodes 1442 are made by a metal mesh 20 arranged on the second substrate 142. In the illustrated embodiment, each of the second sensing electrodes 1442 includes a plurality of sensing units 1444 connected in turn and a wire 1446. The sensing unit 1444 is substantially prismatic, a plurality of sensing units 1144 are connected in turn along the first direction X, i.e. the two opposite corners of one of the sensing units 1444 are connected to a corner of the two adjacent sensing units 1444, respectively. It should be noted that, since the second substrate 144 is substantially rectangular, two of the sensing units 1444 on the two ends are triangular or polygonal for cutting. The sensing units 1444 of the second patterned sensing layer 144 are corresponded to the gaps of the sensing units 1144 of the first patterned sensing layer 144.

The cover plate 170 is bonded to the second pattern sense layer 144 via the second adhesive layer 160. The second adhesive layer 160 is optical adhesive, specifically, the material of the second adhesive layer 160 is silicone or acrylic adhesive. The acrylic adhesive includes acrylic adhesive and methyl acrylic adhesive.

The cover plate 170 is a single layer plate or a multi-layer composite plate formed by tempered glass, polycarbonate (PC), polymethyl acrylate (PMA) or polymethyl methacrylate (abbreviated as acrylic resin). In the illustrated embodiment, the size of the cover plate 170 is substantially the same as the size of the first substrate 112.

The circuit board 180 is a flexible circuit board. In the illustrated embodiment, the circuit board 180 has a control circuit, and the circuit board 180 is electrically connected to the wires 1146 of the first sensing electrodes 1142 of the first patterned sensing layer 114 and the wires 1446 of the second sensing electrodes 1142 of the second patterned sensing layer 144 via a conductive adhesive. Preferably, the conductive adhesive is anisotropic conductive adhesive.

The first patterned sensing layer 114 and the second patterned sensing layer 144 of the touch screen 10 are made of metal mesh, avoiding the use of indium tin oxide, thus the cost of the touch screen 10 is low. Meanwhile, the transmittance of the metal mesh is high.

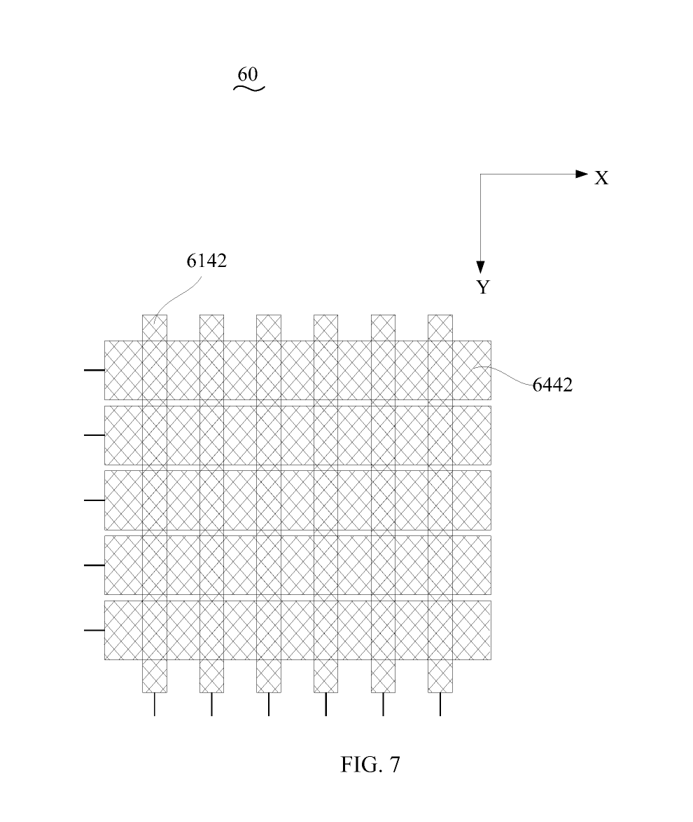

Referring to FIG. 7, the structure of the touch screen 60 of another embodiment is substantially the same as the touch screen 10, the difference is that: the first sensing electrodes 6142 of the touch screen 60 are elongated bars extending along a second direction Y, the second sensing electrodes 6442 are elongated strips extending along a first direction X. In the illustrated embodiment, the width of first sensing electrodes 6142 is smaller than the width of the second sensing electrodes 6442.

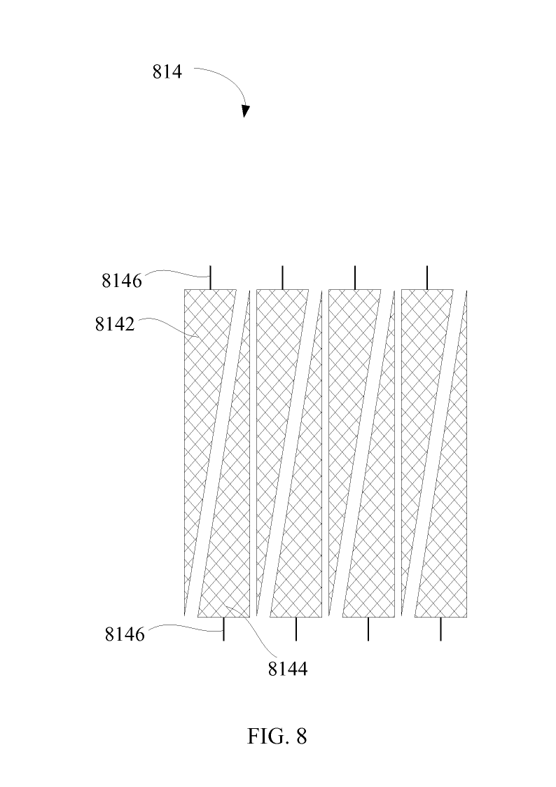

It should be understood that the first adhesive layer 130 and the second capacitive sensing component 140 consisted of the second substrate 142 and the second patterned sensing layer 144 may be omitted. Referring to FIG. 8, and the first patterned sensing layer 814 includes a plurality of first sensing electrodes 8142 and a plurality of second sensing electrodes 8144. The first sensing electrodes 8142 and the second sensing electrodes 8144 are right triangle, and the shapes and sizes of the first sensing electrodes 8142 are the same as that of the second sensing electrodes 8144. The first sensing electrodes 8142 and the second sensing electrodes 8144 are arranged in pairs, the hypotenuses of the first sensing electrodes 8142 and the second sensing electrodes 8144 arranged in pairs are opposite to each other. The shorter right-angle sides of the first sensing electrodes 8142 are collinear. The shorter right-angle sides of the second sensing electrodes 8144 are collinear. In the illustrated embodiment, the shorter right-angle sides of the first sensing electrodes 8142 and the second sensing electrodes 8144 are both provided with a wire 8146. In the illustrated embodiment, the wires 8146 are metal wire, and the wire 8146 and the first sensing electrode 8142 connected to the wire 8146 (or the second sensing electrode 8142) are integrated.

A preparation method of the capacitive sensing component includes the following steps:

S101, a metal layer is formed on a substrate.

In the illustrated embodiment, the metal layer is formed by vacuum evaporation or magnetron sputtering. The metal layer is made of copper, molybdenum-aluminum-molybdenum alloy or copper-nickel alloy. In order to avoid the oxidation of the metal layer, an anti-oxidation layer is formed on the surface of the metal layer by vacuum evaporation or magnetron sputtering. The anti-oxidation layer is made of inert metals, such as gold, platinum or nickel and so on.

S102, the metal layer is processed to form into a metal mesh by exposure and development, and further pattern the metal mesh into a plurality of sensing electrodes arrayed on the substrate. Thus a patterned sensing layer is formed on the substrate.

In the illustrated embodiment, the patterned sensing layer further includes a plurality of wires correspondingly connected to the sensing electrodes, the wires and the corresponding sensing electrodes are integrated.

The patterned sensing layer of the capacitive sensing component is made of metal, the cost is low. Furthermore, the wires and the corresponding sensing electrodes are integrated by exposure and development. which is a high efficient processing method.

A preparation method of the touch screen 10 includes the following steps:

S901, a first capacitive sensing component 110 and a second capacitive sensing component 140 are provided.

In the illustrated embodiment, a preparation method of the first capacitive sensing component 110 includes the following steps: first of all, a metal layer is formed on the first substrate 112; then, the metal layer is processed to form into metal mesh 20 by exposure and development, and further pattern the metal mesh 20 into a plurality of sensing electrodes 1142 arraying on the first substrate 112, thus the patterned sensing layer 114 is formed on the first substrate 112. In the illustrated embodiment, the wires 1146 connected to the first sensing electrodes 1142 and the corresponding first sensing electrodes 1142 are integrated.

The preparation method of the second capacitive sensing component 140 is the same as the preparation method of the first capacitive sensing component 110, which is not described in detail here.

S902, the first capacitive sensing component 110, the second capacitive sensing component 140 and the cover plate 170 are bonded in turn via optical adhesive.

In the illustrated embodiment, the material of optical adhesive is silicone or acrylic adhesive. The acrylic adhesive includes acrylic adhesive and methyl acrylic adhesive.

Specifically, the second substrate 142 of the second capacitive sensing component 140 is bonded to the first patterned sensing layer 114 of the first capacitive sensing component 110 via the first adhesive layer 130, and the first sensing electrodes 1142 of the first patterned sensing layer 114 are arrayed along the first direction (X), the second sensing electrodes 1442 of the second patterned sensing layer 144 are arrayed along the second direction (Y). The cover plate 170 is fixed to the second patterned sensing layer 144 via the second adhesive layer 160.

S903, the first capacitive sensing component 110 and the second capacitive sensing component 140 are electrically connected to the circuit board 180.

In the illustrated embodiment, the circuit board 180 is bonded to the wires 1146 of the first sensing electrodes 1142 of the first patterned sensing layer 114 and the wires 1446 of the second sensing electrodes 1442 of the second patterned sensing layer 144 via the conductive adhesive, therefore, the first capacitive sensing component 110 and the second capacitive sensing component 140 are electrically connected to the circuit board 180. Preferably, the conductive adhesive is anisotropic conductive adhesive.

In the preparation methods of the capacitive sensing component and the touch screen 10, the patterned sensing layer is made of metal, thus the cost is low, and the wires and the corresponding sensing electrodes are integrated by exposure and development, thus it has a higher efficiency.

It should be understood that the second capacitive sensing component 120 may be omitted, and then the first patterned sensing layer 114 of the first capacitive sensing component 110 includes a plurality of first sensing electrodes and a plurality of second sensing electrodes, in the step of S902, the cover plate 180 is bonded to the first patterned sensing layer 114 of the first capacitive sensing component 110 via optical adhesive.

It should be understood that the descriptions of the examples are specific and detailed, but those descriptions can't be used to limit the present disclosure. Therefore, the scope of protection of the invention patent should be subject to the appended claims.

1. A capacitive sensing component, comprising:
a substrate and a patterned sensing layer formed on the substrate, wherein the patterned sensing layer comprises a plurality of sensing electrodes, the plurality of sensing electrodes are formed by a metal mesh arranged on the substrate.

2. The capacitive sensing component according to claim 1, wherein the width of the line of the metal mesh is greater than or equals to 45 nm and less than or equals to 40000 nm.

3. The capacitive sensing component according to claim 1, wherein the metal mesh is made of a material selected from the group consisting of copper, molybdenum-aluminum-molybdenum alloy, and copper-nickel alloy.

4. The capacitive sensing component according to claim 1, wherein a surface of the metal mesh is provided with an anti-oxidation layer, the anti-oxidation layer is made of a material selected from the group consisting of gold, platinum, and nickel.

5. A preparation method of a capacitive sensing component, comprising the following steps:
forming a metal layer on a substrate; and
processing the metal layer to form a metal mesh by exposure and development, and further pattern the metal mesh to a plurality of sensing electrodes arrayed on the substrate, thereby forming a patterned sensing layer on the substrate.

6. The preparation method of the touch screen according to claim 5, wherein the metal layer is made of a material selected from the group consisting of copper, molybdenum-aluminum-molybdenum alloy, and copper-nickel alloy.

7. A touch screen, comprising:
at least one capacitive sensing component, the capacitive sensing component comprising:
a substrate and a patterned sensing layer formed on the substrate, wherein the patterned sensing layer comprises a plurality of sensing electrodes, the plurality of sensing electrodes are formed by a metal mesh arranged on the substrates; and
a cover plate laminated on the patterned sensing layer of the capacitive sensing component.

8. The touch screen according to claim 7, wherein the sensing electrodes comprise a first sensing electrodes and a second sensing electrodes, the first sensing electrodes and the second sensing electrodes are alternately arranged.

9. The touch screen according to claim 7, wherein the number of the capacitive sensing components is two, the substrate of one of the capacitive sensing components is laminated on the patterned sensing layer of the other capacitive sensing component, the sensing electrodes of the patterned sensing layer of one of the capacitive sensing components are arrayed along a first direction, the sensing electrodes of the second patterned sensing layer of the other capacitive sensing component are arrayed along a second direction.

10. The touch screen according to claim 9, wherein the first direction is perpendicular to the second direction.
